(19) United States
(12) Patent Application Publication
(10) Pub. No.: US 2017/0141249 A1
(43) Pub. Date: May 18, 2017

(54) A SILVER PASTE CONTAINING ORGANOBISMUTH COMPOUNDS AND ITS USE IN SOLAR CELLS

(71) Applicant: SUN CHEMICAL CORPORATION, Parsippany, NJ (US)

(72) Inventors: Bo SUN, Bardonia, NY (US); Jin-An HE, Mountain Lakes, NJ (US)

(73) Assignee: SUN CHEMICAL CORPORATION, Parsippany, NJ (US)

(21) Appl. No.: 15/325,572

(22) PCT Filed: Jul. 8, 2015
(86) PCT No.: PCT/US15/39530

§ 371 Date: Jan. 11, 2017

Related U.S. Application Data
(60) Provisional application No. 62/026,836, filed on Jul. 21, 2014.

(51) Int. Cl. H01L 31/0224; H01B 1/22; H01B 1/24; H01L 31/18

(52) U.S. Cl. CPC H01L 31/022425; H01L 31/1804; H01B 1/22; H01B 1/24

(57) ABSTRACT

The present invention is directed to a silver paste for a silicon solar cell comprising an organobismuth additive and a solar cell having a silicon wafer with the silver paste on its front-side surface. The resultant cell exhibits improved efficiency.

This application claims priority to U.S. Provisional Patent Application Ser. No. 62/026,836 filed Jul. 21, 2014, which is incorporated herein by reference in its entirety and for all purposes.

### FIELD OF THE INVENTION

The present invention is directed to a silver paste for a silicon (Si) solar cell comprising organobismuth compounds and a solar cell having a silicon wafer with the silver paste on its front-side surface. The solar cell exhibits improved efficiency resulting from the use of a separate organobismuth additive in the paste.

### BACKGROUND TO THE INVENTION

Silicon solar cells are extensively used in the rapidly growing photovoltaic (PV) industry.

Silicon solar cells typically include a silicon wafer with a silver (Ag) paste screen-printed with a pattern on the front-side (facing the sunlight) of the silicon wafer. The silicon wafer also typically has two overlapping layers containing aluminum and silver respectively printed on the opposite (back-side) of the silicon wafer.

U.S. Pat. No. 5,066,621 and U.S. Pat. No. 5,336,644 are directed to sealing glass compositions containing metal oxides.

U.S. Pat. No. 8,497,420 is directed to a thick film paste containing lead and tellurium oxides and their use in the manufacture of semiconductor devices.

US 2013/0037761 is directed to an electroconductive thick film paste comprising Ag for use in an electrode for a solar cell.

US 2012/0171810 describes paste compositions for an electrode of a solar cell which contains a conductive powder, an organic vehicle and glass frits.

US 2012/0138142 is directed to lead-free and cadmium-free paste compositions for use on contacts for solar cells.

US 2010/0294360 and US 2010/0294361 are directed to a process of forming a front-grid electrode on a silicon wafer with printed and dried metal pastes containing glass frits thereon.

US 2012/0312368 and US 2012/173875 describe an electroconductive thick film paste comprising Ag and Pb free bismuth based oxide both dispersed in an organic medium for the use in the manufacture of semiconductor devices.

US 2011/0147677 is directed to zinc containing glass compositions for use in conductive pastes for silicon semiconductor devices and photovoltaic cells.

WO 2012/0173875 is directed to a thick film paste containing bismuth based oxides and its use in the manufacture of semiconductor devices.

WO 2012/135551 describes high aspect ratio screen printable thick film paste wax compositions for positioning conductive lines on a solar cell device.

Finally Journal Article: Development of lead-free silver ink for front contact metallization Author(s): Kalio, A.; Leibinger, M.; Filipovic, A.; Kruger, K.; Glatthaar, M.; Wilde, J. is directed to solar energy materials and solar cells.

### SUMMARY OF THE INVENTION

The present invention provides a composition for silicon solar cells comprising at least one Ag powder, at least one glass frit, at least one organic resin, at least one solvent and between 0.02 to 5.0 wt % of an organobismuth compound wherein the organobismuth compound is separate from the glass frits.

The present invention also provides a process for preparing a composition which comprises combining at least one Ag powder, at least one glass frit, at least one organic resin, at least one solvent and between 0.02 to 5.0 wt % of an organobismuth compound that is separate from the glass fits.

Additionally the present invention also provides a solar cell comprising a silicon wafer and the composition on the front-side surface of the silicon wafer.

Finally the present invention provides a process for making a solar cell comprising applying a coating of the composition onto the front-side surface of a silicon wafer.

These and other objects, advantages, and features of the invention will become apparent to those persons skilled in the art upon reading the details of the methods and formulations as more fully described below.

### DETAILED DESCRIPTION

It has now been found that the use of silver paste compositions with organobismuth compounds incorporated separately therein as additives and used for front-side silicon solar cell applications results in the production of solar cells with a higher cell efficiency and thus greater power output when exposed to sunlight.

Typically glass frits are added to the silver paste compositions when used in the production of solar cells to etch through the anti-reflective coating (ARC) on the front-side of a silicon wafer.

Furthermore when bismuth compounds have been used in such silver paste compositions they are typically incorporated into the silver paste by melting, at typically temperatures above 1000° C., the compound into glass fits, which are then subsequently quenched and grinded.

However, it has now been found that adding an organobismuth compound as a separate and discrete additive which is not incorporated into glass frits imparts particularly advantageous properties to high efficiency front-side silver paste compositions.

The organobismuth compounds according to the present invention advantageously contain at least bismuth, carbon, hydrogen and oxygen.

Preferably, the compositions comprise between 0.02 to 2.5 wt % of the organobismuth compound and advantageously between 0.1 to 1.5 wt % of the organobismuth compound.

The organobismuth compound may be a liquid at room temperature or may be a solid. Where the organobismuth compound is a solid it typically has a particle size of between 5 nm to 9 μm and preferably a particle size of between 25 nm to 3 μm.

Advantageously, the organobismuth compound is a liquid at room temperature to facilitate processing.

The organobismuth compound is preferably selected from the group consisting of bismuth(III) subsalicylate, bismuth(III) citrate, bismuth(III) acetate, bismuth ethylhexanoate, bismuth hexafluoro-2,4-pentanedionate, bismuth(III) isopropoxide, bismuth trifluoromethanesulfonate hydride, bismuth (III) 2,2,6,6-tetramethyl-3,5-heptanedionate, triphenylbismuth, bismuth 2-ethylhexanoate monoisopropoxide, tris(1-methoxy-2-methyl-2-propoxy)bismuth, bismuth(III) tert-pentyloxide, bismuth(III) trifluoromethanesulfonate, bismuth subgallate hydrate, ammonium bismuth citrate, bismuth(III) 2-naphthol salt, bismuth(III) gallate basic, dichloritri(o-tolyl)bismuth, dichlorodiphenyl (p-tolyl) bismuth, dichlorotris(4-chlorophenyl)bismuth and bismuth neodecanoate and combinations thereof, but is advantageously bismuth ethylhexanoate.

Typically the composition contains between 70 to 95 wt % of Ag powder, and more preferably between 80 to 92 wt %.

Usually the Ag powder has a purity of greater than 99.5% and typically contains impurities such as Zr, Al, Fe, Na, Zn, Pb at advantageously less than 100 ppm.

The Ag powder(s) may be a mixture of one or more Ag powder(s) preferably with a particle size D50 between 0.1 to 5 μm, more preferably between 0.5 to 2 μm.

Usually when two or more Ag powders are used a higher Ag particle packing density is achieved and the proximity of the Ag particles facilitates Ag sintering and percolation during the firing process. This results in a more connected and condensed electron conduction path which generally improves the solar cell efficiency.

The Ag powder(s) are not limited in morphology and may be spherical, elliptical, etc. and typically could be thermally sintered to form a conductive network during the solar cell metallization firing step.

Furthermore the Ag powder(s) may be pre-coated with different surfactants to avoid particle agglomeration and aggregation. The surfactant is advantageously a straight-chain, or branched-chain fatty acid, a fatty acid ester, fatty amide or a mixture thereof.

Additionally long-chain alcohols may also be used for rheology modification.

The composition usually comprises between 0.5 to 10 wt % of glass fits and preferably between 1 to 5 wt % of glass frits.

The glass fits may be formed from the group consisting of PbO, Al₂O₃, SiO₂, B₂O₃, Li₂O, TiO₂, ZnO, P₂O₅, V₂O₅, SrO, CaO, Sb₂O₃, SO₂, As₂O₃, Bi₂O₃, Tl₂O₃, Ga₂O₃, MgO, Y₂O₃, ZrO₂, Mn₂O₅, CoO, NiO, CuO, SrO, Mo₂O₃, RuO₂, TeO₂, CdO, In₂O₃, SnO₂, La₂O₃, BaO and mixtures thereof.

Additionally, the composition preferably contains between 0.2 to 2 wt % of organic resin and more preferably between 0.5 to 1.5 wt %.

Typically the resin is selected from acrylic resin, epoxy resin, phenol resin, alkyd resin, cellulose polymers, polyvinyl alcohol, rosin and mixtures thereof.

Advantageously the resins should burn off during the firing of the coated silicon wafer such that no residue remains thereon.

Additionally, the composition preferably contains between 0.2 to 20 wt % of solvent and more preferably between 2 to 8 wt %.

Typical solvents include texanol, propanol, isopropyl alcohol, ethylene glycol and diethylene glycol derivatives (glycol ether solvents), toluene, xylene, dibutyl carbitol, terpineol and mixtures thereof.

Preferably, the solvents include texanol, butyl carbitol and dibasic ester solvents such as DBE, DBE-6 and DBE-9, obtainable from Invista.

The solvent is effective for dissolving the resins, rosins, and thixotropic agents and is preferably capable of sustaining paste printing whilst subsequently evaporating thoroughly during the drying step.

The composition also typically contains an adhesion promoting agent, thixotropic agent and/or a dispersant.

Usually the composition contains between 0.1 to 0.7 wt % of an adhesion promoting agent, between 0.01 to 3.0 wt % of a dispersant and between 0.1 to 2.0 wt % and advantageously between 0.5 to 2.0 wt % of a thixotropic agent.

Typically the thixotropic agent is a cellulose polymer such as ethyl cellulose, hydroxyethyl cellulose, castor oil, hydrogenated castor oil, an amide modified castor oil derivative or a fatty amide. Suitable thixotropic agents include Thixatrol Max, Thixatrol ST and Thixatrol Pro.

Usually the dispersant is long-chain fatty acid such as stearic acid with functional amine, acid ester or alcohol groups. Suitable dispersants include BYK 108, BYK 111, Solsperse 66000 and Solsperse 27000.

The composition may also contain a metallic oxide additive such as ZnO, and typically contains between 2 to 10 wt % of metallic oxide.

In a preferred embodiment the Ag powder, the organobismuth and the glass fits are mixed with a varnish/vehicle.

A typical vehicle comprises between 3 to 20 wt % of thixotropic agent, between 2 to 30 wt % of resin and between 50 to 95 wt % of solvent usually having a boiling point between 200 to 400° C.

Usually the front-side silver paste composition comprises between 3 to 10 wt % of the vehicle.

The composition is usually in the form of paste and preferably has a viscosity of between 50 to 250 Pa·S at 10 recipocal second.

The present invention also provides a process for making a solar cell which involves applying a coating of the composition onto the front-side surface of a silicon wafer. Furthermore the process usually involves applying two overlapping layers containing aluminum and silver respectively to the back side surface of the silicon wafer. The coated silicon wafer is then fired.

The composition is usually deposited on a silicon wafer by screen/stencil printing. The stroke movement across the screen provides high shear rate to the composition through micro-channels of mesh pattern. The size of micro-channels is preferably 40 to 80 microns for fingers, and preferably 1.0 to 2.0 mm for bus bars. The fingers are preferably narrower in order to leave more open area for sunlight collection whilst the bus bars are preferably dashed rather than continuous due to the cost of Ag. The thickness of the printed finger lines is typically between 10 to 35 microns. Advantageously the higher the printed fingers the better the finger's conductivity.

The manufacturing of silicon solar cells typically includes several steps namely;
i. the transfer of SiO₂ into a Si ingot;
ii. the transfer of the Si ingot to the Si wafer by sawing, etching, doping, ARC and other surface-treatments;
iii. screen-printing and drying the back side silver (Ag) paste on the back side of the wafer;
iv. screen-printing and drying aluminum (Al) paste on the back side of the wafer;
v. screen-printing and drying the front-side silver (Ag) paste on the front side of the wafer;
vi. co-firing the coated wafer in a furnace wherein the wafer goes through a temperature curve optimized for the overall efficiency of the device.

Thus the Al and Ag metals in the two back side coatings form a physical contact with the Si wafer through penetrating SiO₂ on the back side. Furthermore they also form a contact with each other through the overlapping area. The front side Ag paste penetrates the anti-reflection layer and reaches n-type Si beneath it and a good ohmic contact is formed between Ag lines and the n-Si emitter during the firing process. The contact resistance between the Ag lines and the emitter for the current flow is preferred to be minimal to maximize the efficiency of the device. In general, a thin layer of glass frits between the emitter and Ag traces is also preferred and results in higher efficiency.

The invention is further described by the examples given below.

### EXAMPLES

The following examples illustrate specific aspects of the present invention and are not intended to limit the scope thereof in any respect and should not be so construed.

### Example 1: Procedure for Making Ag Paste

### Step 1

The varnish in Table 1 was made by dissolving rosin(s) and thixotropic agent(s) in a solvent (ingredients 1-3). The varnish is a mixture of solvent, thixotropic polymer, resins such as ethylene cellulose, polycarbonate, and rosin such as ester of hydrogenated rosin and hydrogenated castor oil. These can immerse glass frit(s), Ag powders and other solids, and make the paste fluidic enough to be capable of going through stainless-steel-mesh/emulsion channels with 30-100 micron in channel width, 30-55 micron in mesh thickness and 10-30 micron in emulsion thickness, forming paste finger lines on the wafer. However, the varnish preferably allows the printed finger lines to have a thixotropy suitable to minimize the paste from spreading, thus more area is left for capturing sunlight to convert to electricity.

TABLE 1
Varnish Formulation for use with Examples A-F

| | Ingredient | wt. % |
|---|---|---|
| 1 | Ester of Hydrogenated Rosin | 11.5 |
| | (Eastman) | |
| 2 | Crayvallac Super (Arkema) | 14.1 |
| | (thixotropic agent) | |
| 3 | Texanol | 74.4 |
| 4 | Dispersant (Altana BYK) | 0.2 |
| | Total | 100.0 |

### Step 2

The dispersant (ingredient 4) is then added into the above mixture and was aggressively mixed until it became uniform.

TABLE 2
Front-Side Silver Paste formulations

| | Ingredient | Weight/g |
|---|---|---|
| 1 | Ag powder (Ames GoldSmith Corp.) | 82.2 |
| 2 | V2173 (3M Cerodyne Viox Inc.) | 2.5 |
| | Glass Frit | |
| 3 | ZnO (HorseHead Corp.) Additive | 5.5 |
| 4 | Table 1 Varnish | 7.8 |
| 5 | Texanol | 2.0 |
| 6 | Elemental bismuth weight in | 0.18 |
| | organobismuth additives | |
| | (Examples A-E) | |

For examples A, B, C, D and E the elemental bismuth in the organobismuth additives is 0.18 g.

### Step 3

The mixture from step (2) was aggressively mixed with glass frit(s), solvent and additives, including bismuth additives as needed (Table 2—ingredients 2, 3, 4, 5, 6). The glass frits are commercially available lead borosilicate from 3M Cerodyne Viox Inc. and a typical frit such as V2173, V2172, V0981 may be used alone or as the mixture of in the final paste.

### Step 4

Ag powder(s) (ingredient 1) was then added to the step (3) mixture and mixed aggressively with DAC speed mixer from FlackTek Inc.

### Step 5

The mixture from step (4) is then triple-roll milled to a preferred grind of 6-9 μm. The preferred viscosity of the resulting pastes at 10/s is 50-250 Pa·s, more preferably 70-150 Pa·s as measured on AR-2000EX rheometer from TA Instruments.

The three main requirements of the paste are 1) electrical performance, mainly efficiency; 2) green strength (i.e. the lines will hold their integrity and will be resistant to smear during a finger rub test after drying and before firing; 3) ribbon adhesion after firing.

TABLE 3
Inventive Examples A-E; Comparative Example F - Comparison among different
organobismuth compounds

| | | | Electrical Performance | | | | |
|---|---|---|---|---|---|---|---|
| Organobismuth Compound | | | Efficiency | Rs | Voc | Jsc | F.F. |
| Ex. | structure | chemical name | (%) | (Ohm * cm2) | (mV) | (mA/cm2) | (%) |
| A | C₇H₅BiO₄ | Bismuth(III) | 16.4 | 2.15 | 629.4 | 36.2 | 72.1 |
| | | subsalicylate | | | | | |
| B | C₆H₅BiO₇ | Bismuth(III) citrate | 15.4 | 2.12 | 628.1 | 36.3 | 67.5 |
| C | C₆H₉BiO₆ | Bismuth(III) | 16.6 | 3.09 | 630.7 | 36.3 | 72.5 |
| | | acetate | | | | | |
| D | C₂₄H₄₅BiO₆ | Bismuth | 17.1 | 1.60 | 633.4 | 36.3 | 73.8 |
| | | ethylhexanoate | | | | | |
| E | C₃₀H₅₇BiO₆ | Bismuth | 13.1 | 5.87 | 628.8 | 36.3 | 57.5 |
| | | neodecanoate | | | | | |

| | | | | | | |
|---|---|---|---|---|---|---|
| F | Without organobismuth additive | 6.2 | — | 628.4 | 32.2 | 30.2 |

The above table provides a direct comparison of the resulting cell efficiency acquired with an Ag paste with various organobismuth compounds therein compared with the same Ag paste without organobismuth additive. Table 3 shows that Si wafer's efficiency is greatly enhanced by using organobismuth additives (A-E) in comparison with no organobismuth additive (F).

### Solar Cell Fabrication and Test Performance for Pastes:

A 5 inch mono-crystalline wafer with an emitter sheet resistance of 80 to 90 Ohm/square are used in this test and 3 steps as described below are used for preparation: 1) 1.0 g of Al paste is screen-printed on the back-side of each Si wafers, it is then dried using BTU International PVD-600 drying furnace with the setting of belt speed=90 ipm, 310° C. (Zone 1), 290° C. (Zone 2), and 285° C. (Zone 3). The screen used for printing is 325 mesh, 23 micron wire diameter, and 10 micron emulsion, 45 degree bias, the squeegee used is 65-75 shore in hardness; 2) the front-side Ag paste is screen-printed on the front surface of the same wafer and it is dried in the same drying furnace with the setting of belt speed=165 ipm, 340° C. (Zone 1), 370° C. (Zone 2), and 370° C. (Zone 3). The screen used for printing is 325 mesh, 23 micron wire diameter, and 16 micron emulsion, 22.5 degree bias, the squeegee used is 65-75 shore in hardness; 3) the wafers are fired using BTU International PVD-600 firing furnace with the setting of belt speed belt speed=200 ipm, 850° C. (Zone 1), 790° C. (Zone 2), 790° C. (Zone 3), and 1000° C. (Zone 4). The electrical performance (open-circuit voltage Voc (V), efficiency, fill factor, series resistance and shunt resistance in the dark and under light) is measured using a Solar Simulator/I-V tester from PV Measurements Inc. The illumination of the lamp was calibrated using a sealed calibration cell, and the measured characteristics were adjusted to the standard AM1.5 G illumination conditions (1000 mW/cm²). During testing, the cells were positioned on a vacuum chuck located under the lamp and the chuck temperature was maintained at 24° C.+/−1 using a chiller. Both dark and light I-V curves were collected by sweeping voltage between −0.2V and +1.2V and measuring current. Standard solar cell electrical parameters were collected from the instrument including Cell efficiency (%), Series resistance (Rs), Shunt Resistance (Rsh) and Open Circuit Voltage (Voc), short-circuit current (Isc), and short-circuit current density (Jsc). The Cell efficiency 11, is equal to the fill factor and is a key parameter in evaluating the performance of a solar cell. The fill factor is defined as the ratio of the maximum power from the solar cell to the product of Voc and Isc. Graphically, the fill factor is the division of the area of the largest rectangle which could fit between the I-V curve and I/V axes by Isc*Voc. The results were obtained using standard computer software available in the industry for measuring electrical parameters of solar cells.

The present invention has been described in detail, including the preferred embodiments thereof. However, it will be appreciated that those skilled in the art, upon consideration of the present disclosure, may make modifications and/or improvements on this invention that fall within the scope and spirit of the invention.

1. A composition for silicon solar cells comprising:
a) at least one silver powder,
b) at least one glass frit,
c) at least one organic resin,
d) at least one solvent, and
e) between 0.02 to 5.0 wt % of an organobismuth compound wherein the organobismuth compound is separate from the at least one glass frit.

2. (canceled)

3. The composition according to claim 1 wherein the organobismuth compound is a liquid at room temperature; or wherein the organobismuth compound is a solid at room temperature.

4. (canceled)

5. A composition according to claim 1 wherein the organobismuth compound has a particle size of between 5 nm to 9 μm; or
wherein the organobismuth compound has a particle size of between 25 nm to 3 μm.

6. (canceled)

7. The composition according to claim 1 wherein the organobismuth compound is selected from the group consisting of bismuth(III) subsalicylate, bismuth(III) citrate, bismuth(III) acetate, bismuth ethylhexanoate, bismuth hexafluoro-2,4-pentanedionate, bismuth(III) isopropoxide, bismuth trifluoromethanesulfonate hydride, bismuth (III) 2,2,6,6-tetramethyl-3,5-heptanedionate, triphenylbismuth, bismuth 2-ethylhexanoate monoisopropoxide, tris(1-methoxy-2-methyl-2-propoxy)bismuth, bismuth(III) tert-pentyloxide, bismuth(III) trifluoromethanesulfonate, bismuth subgallate hydrate, ammonium bismuth citrate, bismuth(III) 2-naphthol salt, bismuth(III) gallate basic, dichloritri(o-tolyl)bismuth, dichlorodiphenyl (p-tolyl) bismuth, dichlorotris(4-chlorophenyl)bismuth and bismuth neodecanoate and combinations thereof.

8. (canceled)

9. The composition according to claim 1 further comprising an adhesion promoting agent, at least one resin, a thixotropic agent and/or a dispersant; wherein the dispersant is optionally a fatty acid.

10. (canceled)

11. The composition according to claim 1 further comprising an organometal additive selected from the group consisting of organic compounds of zinc, vanadium, barium, and strontium, and combinations thereof.

12. The composition according to claim 1 further comprising a metallic oxide additive; wherein the metallic oxide additive is optionally ZnO.

13. (canceled)

14. The composition according to claim 1 comprising between 70 to 95 wt % of silver powder and/or comprising between 0.5 to 10 wt % of the at least one glass frit and/or comprising between 0.2 to 2 wt % of organic resin and/or comprising between 2 to 20 wt % of solvent.

15. (canceled)

16. The composition according to claim 1, wherein the at least one silver Ag powder has a particle size D50 between 0.1 to 5 μm, or wherein the at least one silver powder has a particle size D50 between 0.5 to 2 μm.

17. (canceled)

18. (canceled)

19. (canceled)

20. The composition according to claim 1, wherein the at least one glass frit is formed from PbO, Al₂O₃, SiO₂, B₂O₃, Li₂O, TiO₂, ZnO, P₂O₅, V₂O₅, SrO, CaO, Sb₂O₃, SO₂, As₂O₃, Bi₂O₃, Tl₂O₃, Ga₂O₃, MgO, Y₂O₃, ZrO₂, Mn₂O₅, CoO, NiO, CuO, SrO, Mo₂O₃, RuO₂, TeO₂, CdO, In₂O₃, SnO₂, La₂O₃, BaO and mixtures thereof.

21. (canceled)

22. (canceled)

23. The composition according to claim 1, wherein the at least one organic resin is selected from acrylic resin, epoxy resin, phenol resin, alkyd resin, cellulose polymers, polyvinyl alcohol, rosin and mixtures thereof.

24. (canceled)

25. (canceled)

26. The composition according to claim 1, wherein the at least one solvent is selected from texanol, propanol, isopropyl alcohol, ethylene glycol and diethylene glycol derivatives, toluene, xylene, dibutyl carbitol, terpineol and mixtures thereof.

27. The composition according to claim 9 comprising between 0.1 to 0.7 wt % of the adhesion-promoting agent and/or comprising between 0.01 to 3.0 wt % of the dispersant and/or comprising between 0.5 to 2.0 wt % of the thixotropic agent.

28. (canceled)

29. (canceled)

30. The composition according to claim 12 comprising between 2 to 10 wt % of the metallic oxide additive.

31. The composition according to claim 1 wherein the composition is in the form of a paste.

32. A process for preparing a composition according to claim 1 comprising combining a silver powder, at least one glass frit, at least one organic resin, at least one solvent and 0.02 to 5.0 wt % of an organobismuth compound that is separate from the glass frits.

33. The process according to claim 32 further comprising:
a) combining the at least one organic resin and the at least one solvent to form a varnish, and
b) adding the Ag silver powder, the at least one glass frit and the organobismuth compound to the varnish and/or
wherein step (a) comprises adding a thixotropic agent and/or wherein step (a) comprises adding a dispersant.

34. (canceled)

35. (canceled)

36. A solar cell comprising a silicon wafer and a composition according to claim 1 on a front side surface of the silicon wafer.

37. A The solar cell according to claim 36 wherein the silicon wafer has two overlapping layers, wherein one layer comprises aluminum and a second layer comprises silver on a back side surface of the silicon wafer.

38. A process for making a solar cell comprising applying a coating of the composition according to claim 1 onto a front side surface of a silicon wafer and/or further comprising applying two overlapping layers wherein one layer comprises aluminum and a second layer comprises silver on a back side surface of the silicon wafer and/or further comprising firing the coated silicon wafer.

39. (canceled)

40. (canceled)
